(19) United States
(12) Patent Application Publication
(10) Pub. No.: US 2026/0030395 A1
(43) Pub. Date: Jan. 29, 2026

(54) METHOD FOR AUTOMATICALLY GENERATING A DESIGN SPECIFICATION FOR A PART, ASSEMBLY, OR STRUCTURE

(71) Applicant: Generative Vision Limited, Worcester (GB)

(72) Inventors: Laurence Cook, Worcester (GB); Nick Arini, Worcester (GB); Nick Boultbee, Worcester (GB); Carlos Rodríguez-Toro, Worcester (GB); Glyn Stevens, Worcester (GB); Ian Mackenzie, Worcester (GB); Sam Phillips, Worcester (GB); Jure Martinec, London (GB)

(21) Appl. No.: 19/277,722

(22) Filed: Jul. 23, 2025

Related U.S. Application Data
(60) Provisional application No. 63/674,637, filed on Jul. 23, 2024.

(51) Int. Cl. G06F 30/12

(52) U.S. Cl. CPC G06F 30/12

(57) ABSTRACT

One variation of a method includes: receiving a descriptor of a design problem; selecting a set of output characteristics based on a set of language signals extracted from the descriptor; selecting a set of functions relating a set of input parameters to the set of output characteristics; accessing a virtual model representing a design solution and defining a set of model variables; linking a subset of input parameters to a subset of model variables analogous to the subset of input parameters; in response to the set of model variables omitting a model variable analogous to a first input parameter in the set of input parameters, prompting a user to update the virtual model to include a first model variable analogous to the first input parameter; and compiling the set of functions, the set of output characteristics, and the set of input parameters into a design specification.

### CROSS-REFERENCE TO RELATED APPLICATIONS

This Application claims the benefit of U.S. Provisional Application No. 63/674,637, filed on 23 Jul. 2024, which is incorporated in its entirety by this reference.

This Application is also related to U.S. patent application Ser. No. 18/965,863, filed on 2 Dec. 2024, which is incorporated in its entirety by this reference.

### TECHNICAL FIELD

This invention relates generally to the field of product design and, more specifically, to a new and useful method for automatically generating a design specification for a part, assembly, or structure in the field of product design.

### BRIEF DESCRIPTION OF THE FIGURES

FIGS. 1A, 1B, and 1C are flowchart representations of a method;

FIGS. 2A and 2B are flowchart representation of one variation of the method; and

FIG. 3 is a flowchart representation of one variation of the method.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. Method: Function+Input Parameter Selection Based on Output Characteristics

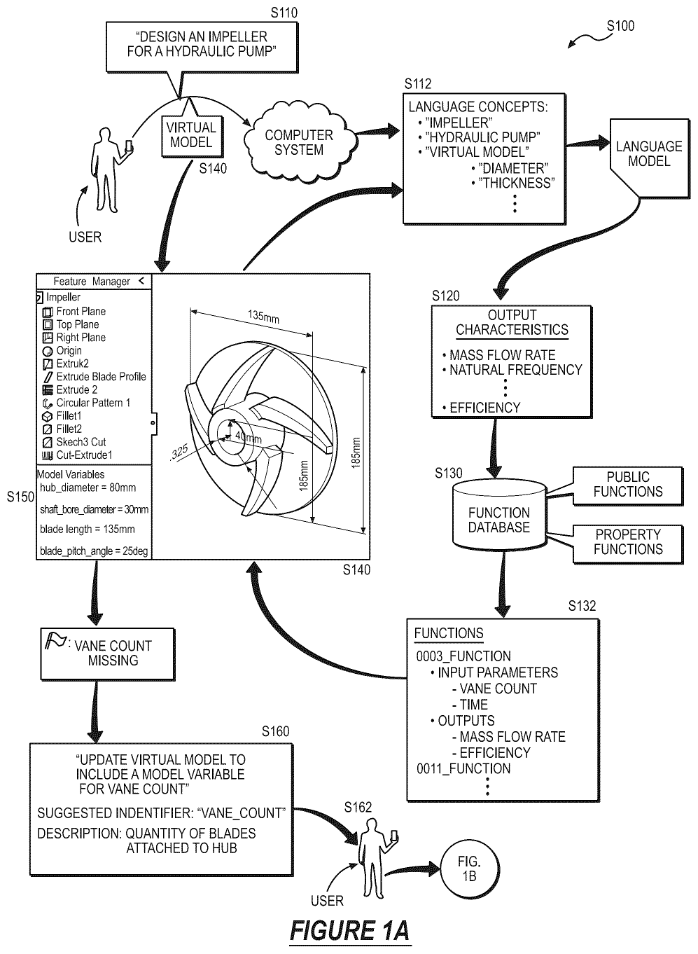

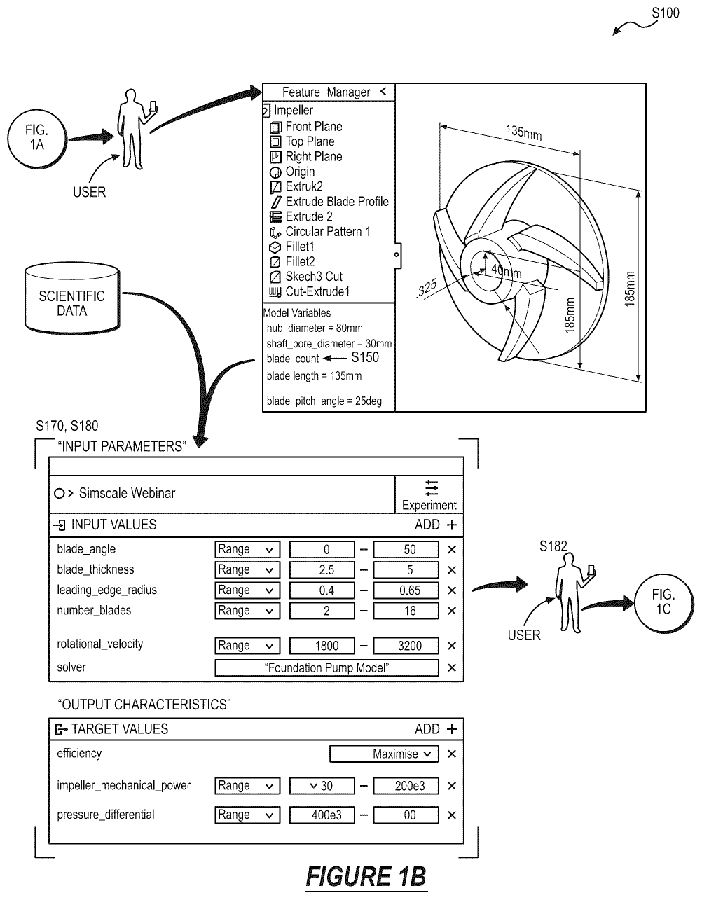

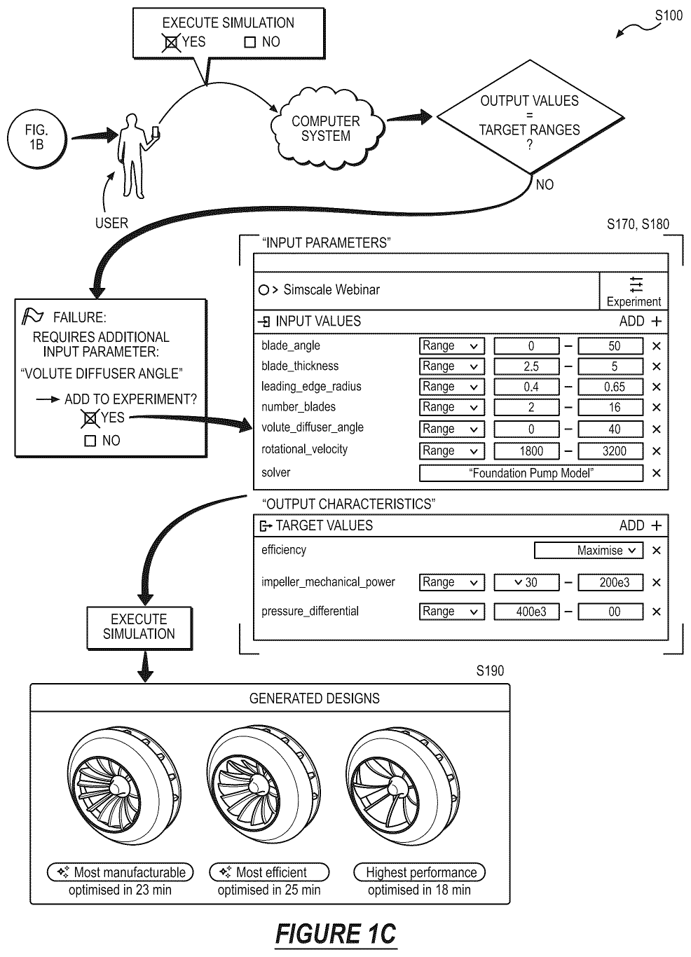

As shown in FIGS. 1A, 1B, 1C, 2A, 2B, and 3, a method S100 includes: accessing a textual descriptor of an engineering design problem, the textual descriptor supplied by a user via a design portal in Block S110; extracting a first set of language signals from the textual descriptor in Block S112; selecting a first set of output characteristics defined for the engineering design problem based on the first set of language signals in Block S120; accessing a function database including a set of functions relating input parameters to output characteristics in Block S130; from the function database, selecting a first subset of functions, in the set of functions, relating a first set of input parameters to the first set of output characteristics in Block S132; accessing a virtual model representing a design solution for the engineering design problem, the virtual model defining a first set of model variables in Block S140; and linking a first subset of input parameters, in the first set of input parameters, to a first subset of model variables, in the first set of model variables, each model variable, in the first subset of model variables, analogous to an input parameter in the first subset of input parameters in Block S150.

The method S100 further includes, in response to the first set of model variables omitting a model variable analogous to a first input parameter in the first set of input parameters: generating a prompt to update the virtual model to include a first model variable analogous to the first input parameter; transmitting the prompt to the user via the design portal in Block S160; and, in response to receiving confirmation of the first model variable in the virtual model, linking the first input parameter to the first model variable and inserting the first input parameter in the first subset of input parameters in Block S150.

The method S100 further includes: for each input parameter, in the first subset of input parameters, defining a range of input values, in a set of ranges of input values, of the input parameter in Block S170; compiling the first set of functions, the first set of output characteristics, the first set of input parameters, and the set of ranges of input values into a design specification for the engineering design problem in Block S180; and presenting the design specification to the user via the design portal in Block S182.

In one variation, the method S100 further includes: selecting a first set of input values for the first set of input parameters based on ranges of input values defined for each input parameter in the set of input parameters; and, based on the first set of input values and the first subset of functions selected for the engineering design problem, executing the virtual model to generate a first set of output values for the set of output characteristics in Block S190.

Additionally, in another variation, the method S100 further includes: for a first output characteristic in the first set of output characteristics, accessing a first target range of values defined for the first output characteristic; and accessing a first output value, in the first set of output values, generated for the first output characteristic. In this variation, the method S100 further includes, in response to the first output value falling outside the first target range of values defined for the first output characteristic: selecting a second set of input values for the first set of input parameters based on ranges of input values defined for each input parameter, in the set of input parameters, and based on a first difference between the first output value and the first target range of values; and, based on the second set of input values and the first subset of functions selected for the engineering design problem, executing the virtual model to generate a second set of output values for the set of output characteristics in Block S190.

1.1 Method: Function+Input Parameter Selection based on Model Variables

As shown in FIGS. 1A, 1B, 1C, 2A, 2B, and 3, one variation of the method S100 includes: accessing a textual descriptor of an engineering design problem, the textual descriptor supplied by a user via a design portal in Block S110; extracting a first set of language signals from the textual descriptor in Block S112; accessing a first set of output characteristics defined for the engineering design problem in Block S120; accessing a virtual model representing a design solution for the engineering design problem, the virtual model defining a first set of model variables in Block S140; accessing a function database including a set of functions relating input parameters to output characteristics in Block S130; and, from the function database, identifying a first subset of functions, in the set of functions, relating a first set of input parameters to the first set of output characteristics, the first set of input parameters analogous to the first set of model variables in Block S132. The method S100 further includes, in response to a first function, in the first subset of functions, defining a first input parameter and in response to the first set of model variables omitting a model variable analogous to the first input parameter: generating a prompt to update the virtual model to include a first model variable analogous to the first input parameter; and transmitting the prompt to the user via the design portal in Block S160.

In one variation, the method S100 further includes: for each input parameter, in the first set of input parameters, defining a range of input values, in a set of ranges of input values, of the input parameter in Block S170; compiling the first subset of functions, the first set of output characteristics, the first set of input parameters, and the set of ranges of input values into a design specification for the engineering design problem in Block S180; and presenting the design specification to the user via the design portal in Block S182.

### 1.2 Deriving a Virtual Model

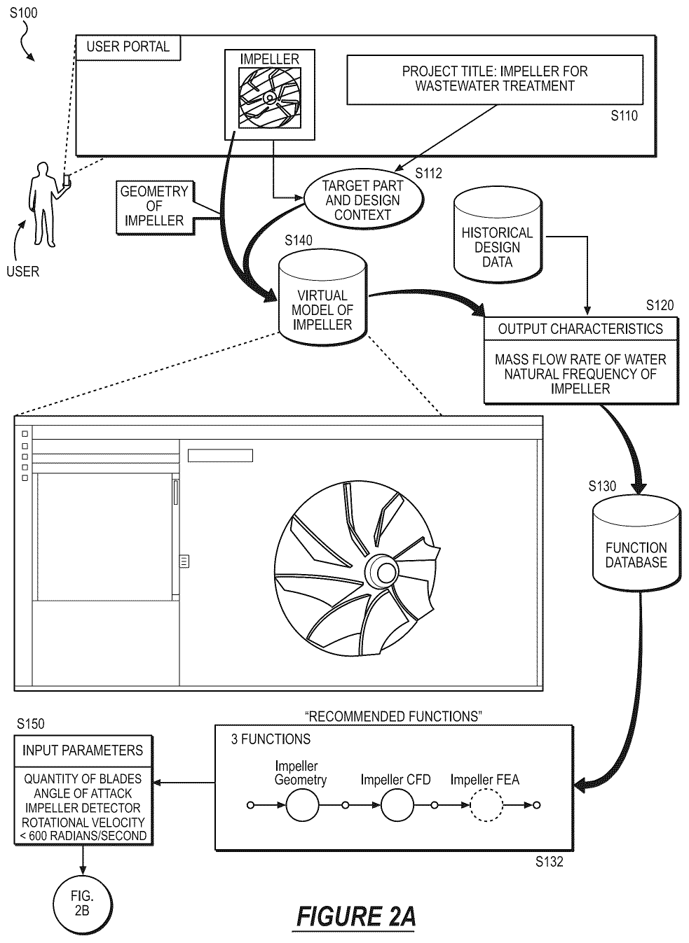

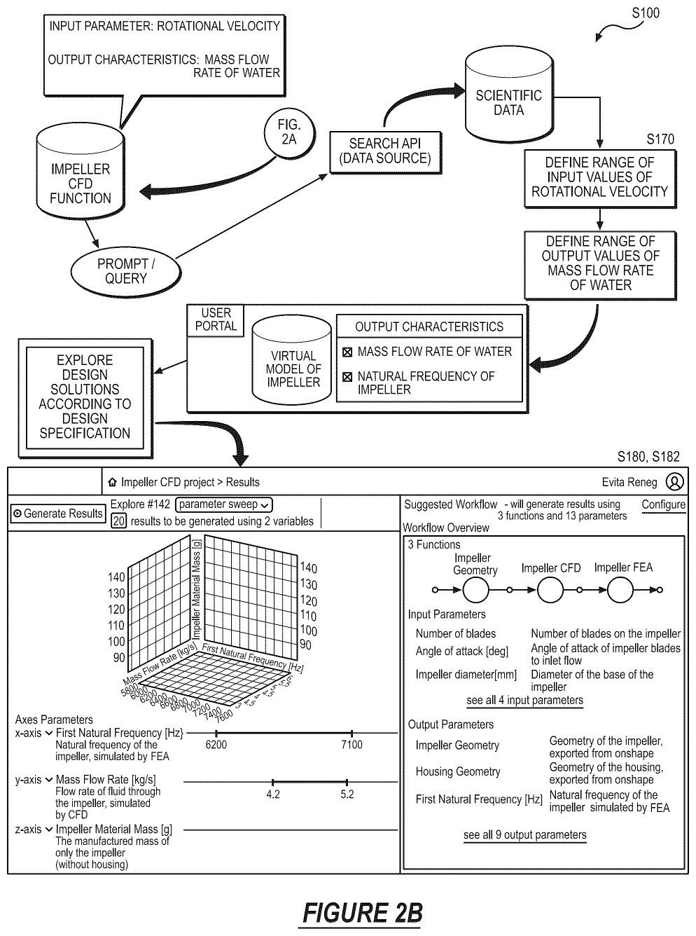

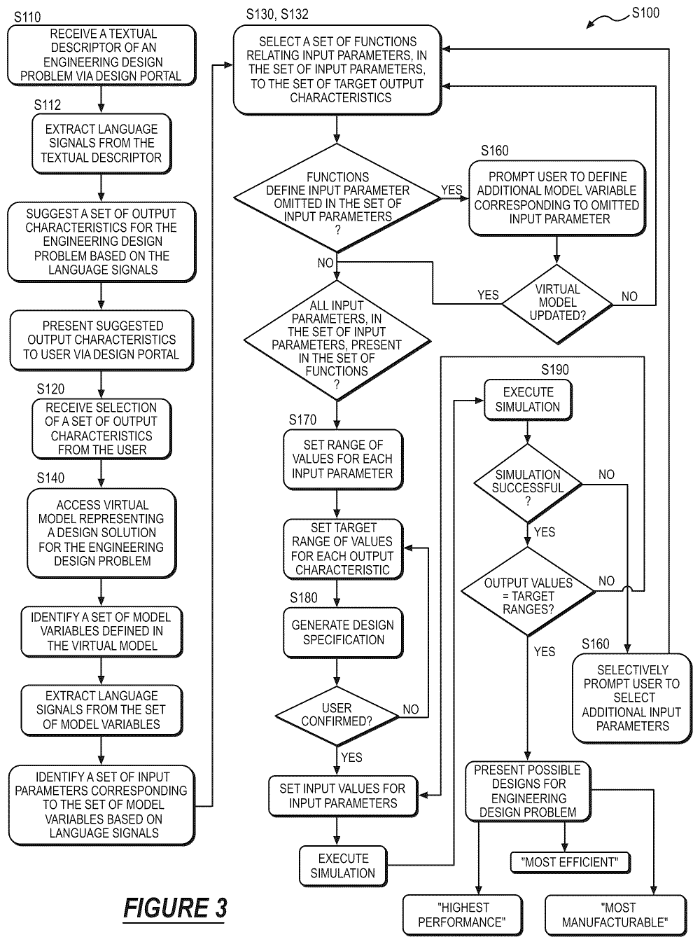

As shown in FIGS. 2A, 2B, and 3, one variation of the method S100 includes: receiving a digital object depicting a target part and a set of natural language terms within a design portal; interpreting a target design context from the set of natural language terms; extracting a set of features representing a geometry of the target part from the digital object; deriving a virtual model of the target part based on the set of features and the target design context; predicting a first set of output characteristics for the target part based on historical design data of the target part and associated with the target design context; accessing a function database; and selecting a set of functions associated with a second set of output characteristics corresponding to the first set of output characteristics within the function database.

The method S100 further includes: for each function in the set of functions: extracting an input parameter, in a set of input parameters, from the function; accessing a corpus of scientific data; and defining a range of input values of the input parameter, in the set of input parameters, based on the corpus of scientific data.

The method S100 also includes presenting the virtual model and the first set of output characteristics for the target part to a user within the design portal. The method S100 further includes, in response to receiving confirmation of the virtual model and the set of output characteristics from the user: compiling ranges of input values and the set of functions into a design specification for the target part; and rendering the design specification for the target part within the design portal.

### 2. Applications

Generally, a computer system (e.g., a computer network, a remote computer system, a remote server, a local device) can execute Blocks of the method S100 to: receive a user query, from a user, describing an engineering design problem and including a set of natural language terms (e.g., a title of a project, a textual description) via a design portal; derive a target design context—representing a particular design solution domain for the design problem of the part from the set of natural language terms; access a virtual model defining geometry (e.g., dimensions, material properties) of the part; identify a target set of output characteristics based on historical output characteristic data of other similar parts for past design problems; select a set of functions (e.g., a mathematical simulation, a numerical model, a complex simulation, a finite element analysis model) within a function library or other database—relating input parameters to output characteristics—that contains output characteristics corresponding to (e.g., matching) the target set of output characteristics; identify a set of input parameters from the selected set of functions; link input parameters, in the set of input parameters, to model variables defined in the virtual model; selectively generate a design specification—defining target ranges of values for the set of input parameters and the set of output characteristics—for the engineering design problem; and present the design specification to the user via the design portal.

Therefore, the computer system can execute Blocks of the method S100 to automatically transform a user query specifying a set of natural language search terms—representing a design problem for a part of interest to the user—into a comprehensive design specification unique to the design problem for the part based on the query and the virtual model; to generate a recommendation for the user to explore possible designs of the part according to the design specification; and to present the design specification and the recommendation to the user.

### 2.1 Target Output Characteristics+Input Parameters

In one implementation, the computer system can retrieve historical output characteristic data for other similar parts, associated with the target design context, for previous design problems explored by the user or previous users. The computer system can select a target set of output characteristics from these historical output characteristic data for the target part, according to a frequency of occurrence of each output characteristic across the previous design problems and/or according to the importance of each output characteristic to a previous user. In one example, the computer system selects a target set of common output characteristics from these historical output characteristic data for the target part. In another example, the computer system selects a target set of output characteristics that previous users manually entered into the design portal and/or manually selected for previous design problems from these historical output characteristic data.

The computer system can present the set of output characteristics to the user within the design portal. The user may therefore view a selection of potential output characteristics—specifically selected for the target part and informed by historical output characteristic data of other similar parts—within the design portal.

Furthermore, the computer system can access a function database (e.g., a data repository, a function library) and select a set of functions—each function in the set of functions associated with a design context corresponding to (e.g., matching to, analogous to) the target design context and containing output characteristics matching the set of target output characteristics—from the function database. The computer system can then identify a set of input parameters defined in the set of functions and predicted to control geometry in the proposed virtual model of the target part.

Furthermore, the computer system can then: extract a set of model variables defined in the virtual model; and attempt to link each input parameter, in the set of input parameters, to a corresponding model variable in the set of model variables defined in the virtual model. In response to failure to link a particular input parameter to a model variable in the set of model variables, the computer system can: prompt the user to define a new model variable—corresponding to the input parameter—in the virtual model, such as in response to predicting that the input variable exhibits a high correlation to one or more output characteristics in the set of output characteristics; and/or automatically assign a fixed value to the input parameter, such as in response to predicting that the input variable exhibits a relatively low correlation to the set of output characteristics.

### 2.2 Proposed Virtual Model

Additionally, in one variation, the computer system can implement artificial intelligence, machine learning, regression, and/or other techniques to autonomously generate a proposed virtual model of the target part based on the target design context, the set of target input parameters, and/or a description of the target part.

For example, the computer system can generate an input prompt: specifying the target design context, a description of the target part, and a set of input parameters to control geometry of the target part; and instructing a generative pre-trained transformer model to generate a virtual model specification for the target part. The computer system then serves the input prompt to the generative pre-trained transformer model for execution. The computer system can receive the virtual model specification and generate a proposed virtual model of the target part according to the virtual model specification.

The computer system can serve the proposed virtual model to the user via the design portal and thus, enable the user to define limited information (e.g., a set of natural language terms and a digital object of the target part) and modify the virtual model to rapidly achieve a virtual model predicted to meet design requirements of the design problem for the target part. Therefore, the computer system, the design portal, and the generative pre-trained transformer can function as a virtual coworker to enable an engineer to quickly explore and develop design solutions for a target part rather than manually conversing with an associate engineer to define geometry, dimensions, material properties, input parameters, output characteristics, and functions to develop design solutions for the target part over a period of time (e.g., 7 days, two weeks).

### 2.3 Allocation of Computational Resources

Accordingly, the computer system can execute Blocks of the method S100 to receive feedback provided by the user—such as responsive to the target set of output characteristics, the target set of input parameters, and the proposed virtual model presented to the user—to selectively modify the corresponding input parameters and input values of these input parameters prior to organizing design requirements into a design specification. Thus, the computer system can control or limit allocation of computational resources to autonomously define ranges of input values of input parameters by avoiding prediction and presentation of additional output characteristics that are not of interest to the user.

The computer system can further control or limit allocation of computational resources to explore many possible design solutions for the part by defining a mesh type and a mesh density (i.e., a quantity of elements per unit area in the mesh) of each function, associated with a selected output characteristic for the part, proportional to a compute duration (e.g., five minutes, 30 minutes, one hour) or acceptable accuracy defined by the user.

### 2.4 Design Specification+Design Solutions

Therefore, the computer system can execute Blocks of the method S100: to function as a virtual coworker that enables an experienced user to quickly explore and develop design solutions for a target part; to streamline a design workflow of a part for an inexperienced user who may exhibit limited knowledge of geometry, dimensions, and/or material properties of the part, relationships of input parameters and output characteristics for the part, functions related to the design problem, and/or expected values of input parameters for a set of functions; and to organize design requirements in a design specification that enables the user to rapidly understand the feasibility of design requirements of the target part in order to a) explore many possible design solutions for the target part according to the design specification and b) complete the design problem while obviating manual drafting, research, and design tests required by the user.

The method S100 is described herein as executed by the computer system to automatically generate a design specification for a part and enable a user to explore possible design solutions for the part according to the design specification. However, the computer system can similarly execute Blocks of the method S100 to automatically generate a design specification for a structure including many parts and enable a user to explore possible design solutions for the structure according to the design specification.

### 3. Input: Digital Object+Textual Description

Block S110 of the method S100 recites accessing a textual descriptor of an engineering design problem, the textual descriptor supplied by a user via a design portal.

Generally, the computer system: interfaces with a design portal (or “design portal”) to receive a design project title to explore design solutions of a target part; and implements machine learning techniques to derive a target design context representing a pending design problem of interest to the user from the design project title.

In one implementation, the computer system interfaces with the design portal to receive a set of natural language terms, entered by a user, representing keywords for a design problem of a target part of interest to the user. In one example, the computer system receives—from a computing device accessed by a user (e.g., a user interface)—a set of keywords specifying a set of natural language terms, such as “Impeller for aerospace.”

Additionally or alternatively, in another implementation, the computer system interfaces with the design portal to receive a digital object (e.g., a sketch, a two-dimensional photographic image, a diagram, a rendering, an engineering drawing, a three-dimensional CAD model) describing (e.g., depicting, representing) a target part, entered by a user.

### 3.1 Language Model+Design Context

Blocks S110 and S112 of the method S100 recite: accessing a textual descriptor of an engineering design problem, the textual descriptor supplied by a user via a design portal; and extracting a first set of language signals from the textual descriptor.

Generally, the computer system can implement machine learning, artificial intelligence, and/or computer vision techniques to derive a design context representing the pending design problem of interest to the user from the natural language terms and/or the digital object describing a target part.

More specifically, the computer system can include a reasoning module (or “language model”) configured to transform a set of natural language terms, entered by the user, into a machine-readable description of the design problem of interest to the user.

In one implementation, the computer system receives a description, such as a project title, specifying a set of natural language terms, and applies the language model to interpret a target part and a target design context from the set of natural language terms. For example, the computer system can: receive a project title specifying a set of natural language terms, such as “Impeller for wastewater treatment”; interpret the target part from the project title, such as “impeller”; and interpret a target design context for the target part, such as “wastewater treatment.” The computer system can then apply the language model to transform the natural language description of the target part and the natural language description of the target design context into a machine-readable description of the design problem.

In another implementation, the computer system: interfaces with the design portal to receive a digital object (e.g., a two-dimensional digital image, a sketch, a diagram), entered by the user, representing a target part and labeled with a set of natural language terms; implements computer vision techniques (e.g., optical character recognition, object recognition) to interpret the set of natural language terms and the target part represented in the digital object; and applies the language model to interpret a target design context from the set of natural language terms and to transform the natural language description of the target part and the natural language description of the target design context into a machine-readable description of the design problem.

### 4. Output Characteristics

Block S120 of the method S100 recites selecting a first set of output characteristics defined for the engineering design problem based on the first set of language signals.

Generally, the computer system can predict a set of output characteristics for the target part based on historical design data for other similar parts associated with the target design context and generate and serve a prompt for the user to confirm the set of output characteristics within the design portal.

In particular, the computer system can: predict a set of output characteristics for the target part based on historical design data for other similar parts, associated with the target design context, for previous design problems of interest to the user or previous users; predict a set of output characteristics for the target part based on historical design data for previous design problems of interest to this particular user or other users; or predict a set of output characteristics for the target part based on historical design data for the target part associated with other design contexts. The computer system can then: present this set of output characteristics to the user via the design portal; receive selection of a subset of output characteristics, in the set of output characteristics, from the user via the design portal; and assign the subset of output characteristics to the engineering design problem accordingly.

In one example, the computer system can: access a textual descriptor of an engineering design problem; extract a set of language signals from the textual descriptor; query a language model for output characteristics of parts related to language signals approximating the set of language signals; and assign a first set of output characteristics—output by the language model—to the engineering design problem.

In one implementation, the computer system retrieves historical output characteristic data for other similar parts, associated with the target design context, for previous design problems. The computer system then selects a set of output characteristics from these historical design data for the target part, associated with the target design context, such as according to a frequency of occurrence of each output characteristic across the previous design problems and/or the importance of each output characteristic to previous users (e.g., manually selected by previous users, manually entered by previous users, confirmed by previous users). The computer system serves the set of output characteristics to the design portal.

### 4.1 Output Characteristic Selection

In one variation, the computer system filters the ranked set of output characteristics to include a particular subset of output characteristics that correspond to output characteristics of functions—stored in a function database (e.g., a data repository, a function library)—associated with the target design context. The computer system then serves the particular subset of output characteristics to the design portal for confirmation by the user.

For example, the computer system can: retrieve historical design data of an impeller for a wastewater treatment application for previous design problems of interest to the user or previous users; select a set of output characteristics from these historical design data of the impeller for the wastewater treatment application; and rank the set of output characteristics according to the importance of each output characteristic to previous users (e.g., manually selected by previous users).

The computer system can further: select a first output characteristic, such as mass flow rate of water, in the ranked set of output characteristics responsive to correspondence between the first output characteristic and a particular output characteristic of a computational fluid dynamics simulation for an impeller; select a second output characteristic, such as a natural frequency of the impeller, in the ranked set of output characteristics responsive to correspondence between the second output characteristic and a particular output characteristic of a finite element method simulation for an impeller; generate a prompt for the user to confirm the mass flow rate of water and the natural frequency of water; and serve the first output characteristic, the second output characteristic, and the prompt within the design portal.

Therefore, the computer system can predict a set of output characteristics of interest to the user and predicted to yield design solutions for the target part rather than deriving all possible output characteristics for the target part. The computer system can thus avoid prediction and presentation of additional output characteristics that are not of interest to the user in order to limit allocation of computational resources to autonomously define ranges of input values of input parameters, as further described below.

### 4.1.1 User Goals: Output Characteristic Selection

In one implementation, the computer system can select the set of output characteristics for the engineering design problem based on a set of user goals specified by the user, such as explicitly and/or implicitly defined in the textual descriptor of the engineering design problem and/or manually supplied by the user (e.g., via the design portal).

In one example, the computer system can: receive the textual descriptor of the engineering design problem; extract a set of language concepts—related to user goals for the engineering design problem—from the textual descriptor; query a language model for output characteristics relevant to the engineering design problem based on the set of language concepts; and retrieve a set of output characteristics—output by the language model—for the engineering design problem. Furthermore, in this example, the computer system can then: generate a prompt to review and/or select output characteristics in the set of output characteristics; transmit the prompt to the user for review of the set of output characteristics; and, in response to user selection of a subset of output characteristics, in the set of output characteristics, assign the subset of output characteristics to the engineering design problem.

Therefore, the computer system can implement a language model (e.g., a large language model) to: automatically generate output characteristics relevant to the engineering design problem and, therefore, more likely to exhibit importance to the user; and enable the user to fine tune selection of output characteristics from a larger list of output characteristics output by the language model.

Additionally or alternatively, in another example, the computer system can prompt the user to provide additional context—such as within a chat window and/or via a “chatbot”—related to a set of goals for the engineering design problem in order to aid selection of output characteristics for the engineering design problem. In particular, in this example, the computer system can: generate a prompt to define a set of user goals for the engineering design problem in language terms; transmit the prompt to the user via the design portal; receive a textual descriptor of the set of goals—such as “cost is not important, but performance matters” or “the highest priority is speed”—via the design portal; extract a set of language concepts from the textual descriptor of the set of goals; query a language model for output characteristics relevant to the engineering design problem based on the set of language concepts; and retrieve a set of output characteristics—output by the language model—for the engineering design problem accordingly.

In a similar example, the computer system can prompt the user to rate a set of predefined engineering goals—such as including accuracy, cost, and speed—for the engineering design problem. In particular, in one example, the computer system can: predefine a set of engineering goals including a first goal associated with accuracy, a second goal associated with cost, and a third goal associated with speed; render a slider tool within the design portal and configured to enable the user to select a particular combination of the first, second, and third goals for the engineering design problem; and define a set of goals for the engineering design problem based on inputs within the slider tool by the user. The computer system can then implement methods and techniques described above to automatically select and/or suggest a set of output characteristics based on the set of goals for the engineering design problem.

Alternatively, in one variation, the computer system can enable the user to manually select the set of output characteristics for the engineering design problem. In particular, in this variation, the computer system can: generate a prompt to select output characteristics, from a set of output characteristics (e.g., including all available output characteristics), for the engineering design problem; transmit the prompt to the user via the design portal; and, in response to receiving selection of a first subset of output characteristics, in the set of output characteristics, from the user via the design portal, assign the first subset of output characteristics to the engineering design problem.

### 5. Function Selection+Input Parameters

Blocks of the method S100 recite: accessing a function database including a set of functions relating input parameters to output characteristics in Block S130; and, from the function database, selecting a first subset of functions, in the set of functions, relating a first set of input parameters to the first set of output characteristics in Block S132.

Generally, once the computer system receives selection of a set of output characteristics from the user, the computer system can access a function database (e.g., a data repository, a function library) and select a set of functions—associated with a second set of output characteristics corresponding to (e.g., matching, analogous to) the selected set of output characteristics—from the function database. The computer system can further extract a set of input parameters from each function in order to control geometry within a proposed virtual model of the target part.

In one implementation, the computer system can: access a function database, each function associated with a particular design context (e.g., aerospace, structural mechanics, thermomechanics, automotive, micromobility, industrial mechanics) and defining an analytical model—such as a mathematical simulation, a numerical model, and/or a complex simulation (e.g., a finite element method simulation, a finite volume body fitted simulation, a computational fluid dynamics simulation)—associated with the particular design context. The computer system can then: select a function from the function database responsive to correspondence between a particular output characteristic defined in the function and a selected output characteristic and responsive to correspondence between a design context associated with the function and the target design context for the target part; and extract a set of input parameters from the function.

For example, the computer system can: access the function database; select a fluid dynamics function (e.g., a computational fluid dynamics simulation) responsive to correspondence (e.g., a match, a correlation) between the particular design context associated with the function and the target design context and responsive to correspondence between a selected output characteristic and a particular output characteristic defined in the fluid dynamics function; and extract a set of variable input parameters, such as a quantity of blades, a base diameter, and an angle of attack for inlet flow, from the fluid dynamics function in order to autonomously predict ranges of input values of each variable input parameter.

Additionally or alternatively, in one implementation, the computer system can query a public library for generic or general engineering design functions representing relationships between a set of input parameters and the set of output characteristics. Alternatively, the computer system can query a proprietary library for functions unique to the user or the user's organization representing relationships between a set of input parameters and the set of output characteristics.

In another implementation, the computer system generates a natural language prompt specifying the textual descriptor for the engineering design problem, an additional textual descriptor (e.g., context information) for the engineering design problem, and a request or an instruction for the language model to return a set of functions required to calculate the set of output characteristics selected by the user. For example, the computer system can generate a natural language prompt specifying: the textual descriptor, such as “We are designing an impeller for a hydraulic pump for actuating flaps in a large commercial aircraft”; context information, such as “We are preparing to run FEA on a CAD model”; and instructions for the language model, such as “return a list of functions from public and proprietary function libraries in order to calculate mass flow rate, pressure, volume flow rate, efficiency, and resonant frequency as a function of impeller speed, vane count, vane height, vane angle of attack, outer diameter, and shaft diameter.” Accordingly, the computer system: receives a response from the language model specifying a set of functions; and assigns the set of functions—returned from the language model—to the engineering design problem.

### 5.1 Function Selection: Engineering Goals

In one variation, the computer system can select a particular subset of functions, in the set of functions defined in the function database, based on the set of output characteristics and a set of goals defined for the engineering design problem.

For example, the user may define a goal of speed—for a first iteration of the virtual model—with less focus on accuracy. In this example, the computer system can select a subset of functions, in the set of functions, configured to output relatively less accurate values for the set of output characteristics at a relatively higher speed. Alternatively, in another example, the user may define a goal of accuracy—such as for a second iteration of the virtual model—with less focus on speed. In this example, the computer system can select a subset of functions, in the set of functions, configured to output relatively accurate values for the set of output characteristics at a relatively reduced speed. Therefore, the computer system can selectively identify a particular group of functions—predicted to yield the set of output characteristics—in order to achieve a particular design goal defined by the user in the design portal.

In one implementation, the computer system can select a particular combination of functions configured to minimize a quantity of input parameters required for the engineering design problem. In particular, in this implementation, the computer system can: access a set of output characteristics defined for the engineering design problem; access the function database including a set of functions relating input parameters to output characteristics; and select a subset of functions, in the set of functions, relating a set of input parameters to the set of output characteristics, the subset of functions defining a quantity of unique input parameters less than each other subset of functions, in the set of functions, configured to yield the first set of output characteristics.

For example, the computer system can: identify a first subset of functions, in the set of functions, defining a first quantity of input parameters related to the set of output characteristics; identify a second subset of functions, in the set of functions, defining a second quantity of input parameters related to the set of output characteristics; and identify a third subset of functions, in the set of functions, defining a third quantity of input parameters related to the set of output characteristics. Then, in this example, in response to the first quantity falling below the second quantity and the third quantity, the computer system can select the first subset of functions for the engineering design problem.

Additionally or alternatively, in another implementation, the computer system can select a particular combination of functions configured to minimize a quantity of functions required for the engineering design problem. In particular, in this implementation, the computer system can: access a set of output characteristics defined for the engineering design problem; access the function database including a set of functions relating input parameters to output characteristics; and select a subset of functions, in the set of functions, relating a set of input parameters to the set of output characteristics, the subset of functions including a quantity of functions less than each other subset of functions, in the set of functions, configured to yield the first set of output characteristics.

For example, the computer system can: identify a first subset of functions, in the set of functions, including a first quantity of functions relating a first set of input parameters to the set of output characteristics; identify a second subset of functions, in the set of functions, including a second quantity of functions relating a second set of input parameters to the set of output characteristics; and identify a third subset of functions, in the set of functions, including a third quantity of functions relating a third set of input parameters to the set of output characteristics. Then, in this example, in response to the first quantity falling below the second quantity and the third quantity, the computer system can select the first subset of functions for the engineering design problem.

### 6. Virtual Model

Block S140 of the method S100 recites: accessing a virtual model representing a design solution for the engineering design problem.

Generally, the computer system can access a virtual model—such as a three-dimensional computer-aided design model defining a geometry, dimensions, and/or material properties of a part or assembly—for the engineering design problem via the design portal.

### 6.1 Link to Model Variables in Virtual Model

Block S150 of the method S100 recites: linking a first subset of input parameters, in the first set of input parameters, to a first subset of model variables, in the first set of model variables, each model variable, in the first subset of model variables, analogous to an input parameter in the first subset of input parameters.

Generally, the computer system can extract a set of model variables defined in the virtual model for the engineering design problem. The computer system can then: access the set of input parameters defined by the set of functions selected for the engineering design problem; and attempt to link each input parameter, in the set of input parameters, to a corresponding model variable in the set of model variables defined in the virtual model. For example, the computer system can: identify a first input parameter defined in a first subset of functions in the set of functions selected for the engineering design problem; scan the set of model variables for a corresponding model variable; and, in response to identifying a first model variable, in the set of model variables, corresponding to the first input parameter, link the first input parameter to the first model variable in the virtual model. The computer system can repeat this process for each input parameter, in the set of input parameters, to: link a second input parameter to a second model variable in the virtual model; link a third input parameter to a third model variable in the virtual model; etc.

In one implementation, the computer system can leverage language signals—extracted from model variables defined in the virtual model—and a language model to selectively link input parameters to model variables in the virtual model. For example, the computer system can: identify a first input parameter—including a first description—defined in a first subset of functions in the set of functions selected for the engineering design problem; identify a first model variable, in a set of model variables, defined in the virtual model; extract a first set of language signals from the first model variable defined in the virtual model; derive a first correlation between the first set of language signals and the description of a first input parameter; and, in response to the first correlation exceeding a threshold correlation, link the first model variable to the first input parameter. Additionally or alternatively, in this example, the computer system can: identify a second input parameter—including a second description—defined in a second subset of functions in the set of functions selected for the engineering design problem; identify a second model variable, in the set of model variables, defined in the virtual model; extract a second set of language signals from the second model variable defined in the virtual model; derive a second correlation between the second set of language signals and the description of the second input parameter; and, in response to the second correlation falling below the threshold correlation, reject linking of the second model variable to the second input parameter. The computer system can then repeat this process to attempt to link the second input parameter to a third model variable in the set of model variables accordingly.

### 7. Model Missing Corresponding Variables

Block S160 of the method S100 recites: generating a prompt to update the virtual model to include a first model variable analogous to the first input parameter; and transmitting the prompt to the user via the design portal.

Generally, the computer system can selectively prompt the user to define an additional model variable in the virtual model in response to one or more selected functions including an input parameter lacking correspondence to a model variable in the virtual model.

In particular, the computer system can: implement the methods and techniques described above to select a set of functions for the engineering design problem; identify a set of input parameters defined by the set of functions; extract a set of model variables defined in the virtual model; and attempt to map the set of input parameters to the set of model variables. Then, in response to the set of model variables omitting a model variable analogous to a first input parameter, in the set of input parameters, the computer system can: generate a prompt to update the virtual model to include a first model variable analogous to the first input parameter; and transmit the prompt to the user via the design portal.

In one implementation, the computer system can append the prompt with a description of the required model variable and/or a recommended identifier (e.g., name) for the model variable in the virtual model. In particular, the computer system can: generate a description of the (missing) model variable corresponding to an input parameter defined by the set of functions selected for the engineering design problem; generate a recommended identifier for the model variable in the virtual model; generate a prompt—including the description and the recommended identifier—to update the virtual model to include the model variable; and transmit the prompt to the user (e.g., via the design portal).

For example, the computer system can: generate a description of “a height of each vane nearest the center of the impeller”; generate a recommended identifier of “vane_height_inner”; generate a prompt—including the description and recommended identifier—to update the virtual model to include a model variable for inner vane height; and transmit the prompt to the user via the design portal.

Therefore, the computer system can automatically prompt the user to define additional model variables within the virtual model based on the set of functions—and corresponding input parameters—selected for the engineering design problem, without requiring the user to initially define all possible model variables and/or research required model variables for the engineering design problem.

### 7.1 Model Missing Corresponding Variables: Identify Highest-Priority Input Parameters

In one implementation, the computer system can identify a set of high priority input parameters, in the set of input parameters, defined by the set of functions selected for the engineering design problem. The computer system can then: prioritize linking of these high-priority input parameters to model variables in the virtual model; and deprioritize linking of lower-priority input parameters to model variables in the virtual model.

For example, the computer system can: access a set of output characteristics defined for the engineering design problem; access a function database including functions relating input parameters to output characteristics; select a set of functions relating a set of input parameters to the set of output characteristics defined for the engineering design problem; identify a first subset of input parameters, in the set of input parameters, predicted to exhibit a high correlation to the set of output characteristics; identify a second subset of input parameters, in the set of input parameters, predicted to exhibit a low correlation to the set of output characteristics; and, for each input parameter in the first subset of input parameters, attempt to link the input parameter to a model variable in a set of model variables defined by the virtual model for the engineering design problem. In response to failure to link a particular input parameter, in the first subset of input parameters, to a model variable in the set of model variables, the computer system can prompt the user to define a corresponding model variable in the virtual model.

Furthermore, in the preceding example, the computer system can: prompt the user to define a set of fixed values for input parameters in the second subset of input parameters predicted to exhibit a low correlation to the set of output characteristics; and/or implement methods and techniques described above to automatically select a set of fixed values for input parameters in the second subset of input parameters.

In one example, the computer system can: identify a set of 5 highest-priority input parameters; ensure each input parameter in the set of 5 highest-priority input parameters corresponds to a model variable in the set of model variables defined in the virtual model; and automatically fix all other input parameters, regardless of whether the input parameter corresponds to a model variable defined in the virtual model.

The computer system can therefore: prioritize selection of input parameters predicted to exhibit a greatest effect on the set of output characteristics; and avoid overloading the user with additional work updating the virtual model.

### 7.2 Model Missing Corresponding Variables: Assign Fixed Values

In one implementation, the computer system can assign a fixed value to an input parameter, in the set of input parameters, omitting an analogous model variable in the virtual model.

In particular, in this implementation, the computer system can link a first subset of input parameters, in a set of input parameters defined by a selected set of functions, to a set of model variables defined in the virtual model, each input parameter, in the first subset of input parameters, analogous to a model variable in the set of model variables. Then, for each input parameter, in a second subset of input parameters, in the set of input parameters and omitted from the first subset of input parameters, the computer system can assign a fixed value, in a set of fixed values, to the input parameter. The computer system can thus assign a fixed value to any remaining input parameter—unmatched to a model variable defined in the virtual model—defined by the set of functions selected for the engineering design problem.

For example, the computer system can: implement the methods and techniques described above to select a set of functions for the engineering design problem; identify a set of input parameters defined by the set of functions; extract a set of model variables defined in the virtual model; and, in response to the set of model variables omitting a model variable analogous to a first input parameter, in the set of input parameters, generate a prompt to update the virtual model to include a first model variable analogous to the first input parameter. The computer system can then: transmit the prompt to the user via the design portal; and, in response to the user electing to omit the first model variable in the virtual model, generate a prompt to define a fixed value for the first input parameter and transmit the prompt to the user. Additionally or alternatively, the computer system can automatically select a fixed value for the first input parameter, such as by querying the language model to provide the fixed value for the first input parameter. Therefore, in this example, the computer system can enable the user to selectively define a new model variable—corresponding to the first input parameter—or fix the first input parameter accordingly for execution of the set of functions.

### 8. Model Defines Excess Variables

In one implementation, the computer system can prompt the user to remove a model variable, in the set of model variables, defined in the virtual model and/or provide a fixed value for the model variable in response to absence of a corresponding input parameter in the set of input parameters defined by the set of selected functions.

In particular, in this implementation, the computer system can: implement the methods and techniques described above to select a set of functions for the engineering design problem; identify a set of input parameters defined by the set of functions; extract a set of model variables defined in the virtual model; and attempt to map the set of input parameters to the set of model variables. Then, in response to the set of model variables including a first model variable lacking correspondence to an input parameter, in the set of input parameters, the computer system can: generate a prompt to update the virtual model to remove the first model variable from the virtual model; and transmit the prompt to the user via the design portal. Additionally or alternatively, in response to the set of model variables including the first model variable lacking correspondence to an input parameter, in the set of input parameters, the computer system can: generate a prompt to provide a fixed value for the first model variable; and transmit the prompt to the user via the design portal.

In particular, in this implementation, in response to the set of model variables including the first model variable lacking correspondence to an input parameter in the set of input parameters defined by the set of functions, the computer system can: generate a prompt including a request to discard the first model variable from the virtual model; transmit the prompt to the user via the design portal; and, in response to rejection of the request to discard the first model variable from the virtual model by the user, assign a fixed value to the first model variable.

Therefore, the computer system can enable the user to select whether to remove the first model variable from the virtual model or assign a fixed value to the first model variable.

Alternatively, the computer system can enable the user to reject the prompt entirely and retain the first model variable within the virtual model. In this implementation, the computer system can: derive an estimated time delay in execution of the virtual model if the first model variable is included in the virtual model; and include this predicted estimated time delay in the prompt transmitted to the user. Therefore, the user may select whether to include the first model variable in the virtual model based on the predicted time delay accordingly.

Additionally or alternatively, in one implementation, in response to the user rejecting the prompt to remove the model variable from the virtual model, the computer system can select an additional function—including an input parameter corresponding to the model variable—for the engineering design problem. In particular, in this implementation, in response to the set of model variables including a first model variable lacking correspondence to an input parameter, in the set of input parameters, the computer system can: generate a prompt including a request to discard the first model variable from the virtual model; transmit the prompt to the user via the design portal; and, in response to rejection of the request to discard the first model variable from the virtual model by the user, select a new function, in the set of functions in the function database, defining a first input parameter analogous to the first model variable.

### 9. Variation: Select Functions Based on Defined Model Variables

In one variation, Blocks of the method S100 recite: accessing a virtual model representing a design solution for the engineering design problem, the virtual model defining a first set of model variables in Block S140; accessing a function database including a set of functions relating input parameters to output characteristics in Block S130; and, from the function database, identifying a first subset of functions, in the set of functions, relating a first set of input parameters to the first set of output characteristics, the first set of input parameters analogous to the first set of model variables in Block S132.

Generally, in this variation, the computer system leverages the set of model variables defined in the virtual model to select a subset of functions, in the set of functions in the function database, that include input parameters analogous to the set of model variables.

In particular in this variation, the computer system can: access a textual descriptor of an engineering design problem (e.g., via the design portal); extract a set of language signals from the textual descriptor; implement methods and techniques described above to access a set of output characteristics defined for the engineering design problem; access a virtual model (e.g., a three-dimensional computer-aided design model)—defining a first set of model variables—representing a design solution for the engineering design problem; access the function database including a set of functions relating input parameters to output characteristics; and, from the function database, identify a first subset of functions, in the set of functions, relating a first set of input parameters—analogous to the first set of model variables—to the first set of output characteristics. The computer system can thus narrow a search for functions, in the set of functions, corresponding to the set of output characteristics based on the first set of model variables already defined in the virtual model.

Therefore, in this variation, the computer system can: prioritize selection of functions that include input parameters analogous to the set of model variables; and deprioritize and/or limit selection of functions that include input parameters lacking correspondence to model variables in the set of model variables defined in the virtual model, thereby reducing a workload of the user responsible for updating the virtual model to include additional required model variables.

### 10. Absence of Virtual Model

Generally, responsive to absence of a virtual model, such as a computer-aided design model or a three-dimensional model, of the target part, the computer system can implement artificial intelligence, machine learning, regression and/or other techniques to automatically generate a proposed virtual model of the target part or retrieve a template virtual model of the target part from a template database.

In one implementation, responsive to absence of a virtual model, the computer system can: implement artificial intelligence, machine learning, regression and/or other techniques to automatically generate a proposed virtual model of the target part based on a description of the target part, the target design context, and/or input parameters to control geometry of the target part.

In another implementation, responsive to absence of a virtual model, the computer system can retrieve a template virtual model of the target part from a template database—including template geometries, dimensions, and/or material properties of parts for past design problems entered by previous users or of common parts—according to the target design context.

### 10.1 Proposed Virtual Model

Generally, when an existing virtual model of the target part is absent, the computer system can generate an input prompt instructing a generative pre-trained transformer model (e.g., a large language model) to generate a virtual model (e.g., a three-dimensional model, a computer-aided design model) specification for the target part.

In one implementation, the computer system generates an input prompt specifying the target design context, a description of the target part, and a set of input parameters to control geometry of the target part and instructing the generative pre-trained transformer model to generate a virtual model specification for the target part. The computer system then serves the input prompt to the generative pre-trained transformer model—via an application programming interface—for execution. Accordingly, the computer system: receives the virtual model specification via the application programming interface; generates a proposed virtual model of the target part according to the virtual model specification; and renders the proposed virtual model of the target part within the design portal.

For example, the computer system can generate an input prompt: specifying a hydraulic impeller for a wastewater treatment application and a set of input parameters, such as a quantity of blades, an angle of attack, an impeller diameter, a null pressure at an inlet of the impeller, a null pressure at the outlet of the impeller, and a rotational velocity; and instructing the generative pre-trained transformer model to generate a computer-aided design model specification for the impeller. The computer system can, via an application programming interface: serve the input prompt to the generative pre-trained transformer model for execution; and receive a machine-readable description of a computer-aided design model for the impeller. The computer system can then: generate a proposed virtual model of the target part according to the machine-readable description of a computer-aided design model for the impeller; and render the proposed virtual model of the target part within the design portal.

Therefore, the computer system can generate a proposed virtual model of the target part of the particular design context with limited information from the user who may want to explore possible geometries for the target part prior to manually uploading a virtual model within the design portal or who may exhibit limited knowledge of constructing a virtual model (e.g., a computer-aided design model) for the target part. The computer system can thus, enable the user to quickly review design solutions of the target part and to further refine the design solutions with an additional query to solve the design problem without manually defining: a virtual model; a set of input parameters; a set of output characteristics; and ranges of input values of the set of input parameters and output values of the set of output characteristics prior to interfacing with the design portal.

### 10.2 Template Virtual Model

In one implementation, the computer system: interfaces with the design portal to detect absence of a virtual model of the target part; and selects a template virtual model of the target part within a template database in order to define a set of template input parameters for the target part.

In one variation, the computer system: accesses a template database representing template virtual models including template geometries (e.g., dimensions, material properties) of parts for past design problems entered by previous users; retrieves a template virtual model of the target part from the template database responsive to correspondence between a design context associated with the template virtual model and the target design context for the target part; extracts a set of features representing geometry, dimensions, and/or material properties from a digital object of the target part provided by the user; and updates the template virtual model with the set of features to derive a proposed virtual model of the target part exhibiting the geometry represented in the digital object.

In another variation, the computer system: maintains a template database or multi-dimensional (e.g., “n-dimensional”) space storing a corpus (e.g., hundreds, thousands) of containers (e.g., matrices, vectors) embodying multiple (e.g., “n-number” of) features—such as geometries, material properties, dimensions, constraints, variables, etc.—detected and extracted from past virtual models of parts for past design problems entered by previous users; groups a set of containers by a particular part and/or design context within the template database; and groups these containers into clusters of containers exhibiting (relatively) high degrees of similarity in dimensions of the template database.

For example, the computer system can: scan the template database for a virtual model of the target part; identify a set of containers representing virtual models of the target part and associated with a design context corresponding to the target design context; extract a common set of features from the set of containers; and generate a template virtual model of the target part for the target design context based on the common set of features.

Alternatively, the computer system can: transform each cluster of containers into a template set of features (e.g., geometries, material properties, dimensions, constraints, variables) for a particular part without a design context; maintain a template database of containers; select a container of a particular part corresponding to the target part from the template database; and generate a template virtual model of the target part from the set of features represented in the container; extract a second set of features representing geometry from a digital object of the target part provided by the user; and update the template virtual model with the second set of features to derive a proposed virtual model of the target part exhibiting the geometry, defined by the user. Thus, the computer system can generate a template virtual model from a set of common features for a similar part and update (e.g., modify) the template virtual model with current geometry of the target part in order to derive a proposed virtual model of the target part.

Therefore, the computer system can present a proposed virtual model of a target part to the user and thereby enable the user: to review the proposed virtual model of the target part who may exhibit limited knowledge of geometry (e.g., dimensions, material properties) for the target part; and to quickly modify the proposed virtual model of the target part without manually defining a virtual model in the design portal.

### 10.2.1 Virtual Model+Input Parameter Selection

In one variation, responsive to selection of a set of output characteristics and confirmation of a template virtual model of the target part from the user, the computer system implements computer vision techniques (e.g., optical character recognition techniques or object recognition techniques) to interpret a set of input parameters from the proposed virtual model of the target part. In particular, the computer system: extracts a set of features representing geometry of the target part for parameterization from the virtual model; and identifies the set of features as a set of input parameters for the target part.

For example, the computer system can access a three-dimensional computer-aided design model of a van panel defining geometry, such as a set of dimensions (e.g., a total width of 127.215 millimeters, a first radius of curvature of 1001.474 millimeters, and a second radius of curvature of 446.947 millimeters) and/or material properties of the van panel. The computer system can then: derive a set of features of the van panel from the virtual model such as a pocket depth, a pocket width, a pocket rotation angle, and/or a draft angle, from the geometry of the van panel defined in the three-dimensional computer-aided design model; identify the set of features as a set of input parameters; and autonomously derive input values of input parameters and output values of output characteristics for the van panel, as further described below.

### 11. Autonomously Defined Value Ranges

Block S170 of the method S100 recites for each input parameter, in the first subset of input parameters, defining a range of input values, in a set of ranges of input values, of the input parameter.

The computer system can further access one (or multiple) resource databases and scan this resource database for scientific data associated with the target part and the design context linked to each function. The computer system can then define a range of input values of each input parameter and a range of output values of each output characteristic from these scientific data for each function.

Additionally or alternatively, the computer system can further implement the language model or a large language model (e.g., an LLM) to interpret a set of language concepts from the target design context. The computer system can then: access one (or multiple) resource databases and scan this resource database for scientific data associated with the target part and the target design context; and define a range of input values of each target input parameter and a range of output values of each target output characteristic from these scientific data.

Furthermore, the computer system can: implement artificial intelligence, machine learning, and/or other techniques to search a corpus of scientific data in order to autonomously define ranges of input values of input parameters and ranges of output values of output characteristics, defined in each function and mapped to model variables and output characteristics derived from the virtual model or query.

In particular, in one implementation, the computer system can: access a set of output characteristics defined for the engineering design problem; access a function database including functions relating input parameters to output characteristics; and select a set of functions relating a set of input parameters to the set of output characteristics defined for the engineering design problem. Then, for each input parameter, in the set of input parameters, the computer system can: query a language model for scientific data associated with the input parameter; retrieve a corpus of scientific data, for the input parameter, output by the language model; and, based on the corpus of scientific data, define the range of input values of the input parameter.

### 12. Design Specification+Design Solutions

Blocks S180 and S182 of the method S100 recite: compiling the first set of functions, the first set of output characteristics, the first set of input parameters, and the set of ranges of input values into a design specification for the engineering design problem; and presenting the design specification to the user via the design portal.

Generally, the computer system can compile ranges of input values, ranges of output values, and the set of functions into a design specification for the target part and return the design specification for the target part to the design portal.

In one implementation, the computer system can: compile ranges of input values, ranges of output values, and the set of functions into a design specification for the target part; transform the design specification into human-readable text via the language model; generate a visual representation of the design specification (e.g., a list, a table, a graphical outline)—defining ranges of input values of input parameters, and ranges of output values of output characteristics for the set of functions—for the target part; generate a recommendation for the user to explore possible designs of the target part according to the design specification; and present the visual representation of the design specification for the target part and the recommendation within the design portal for the user to review. In one example, the computer system can present a set of possible designs for the user to explore, each possible design, in the set of possible designs, corresponding to a particular design goal. In particular, in this example, the computer system can generate: a first possible design corresponding to a first goal of a “most manufacturable” design; a second possible design corresponding to a second goal of a “most efficient” design; and a third possible design corresponding to a third goal of a design exhibiting a “highest performance.” Therefore, the computer system can reduce a quantity of possible designs presented to the user, while enabling the user to review a variety of possible designs configured to achieve different goals.

Therefore, the computer system can: compile ranges of input values of input parameters, ranges of output values, and the set of functions into a design specification, specifying human-readable text, and render a visual representation of the design specification within the design portal.

Accordingly, the computer system can: receive confirmation of the design specification; feed the proposed virtual model of the part and input values of input parameters into each function, defined in the design specification, and execute the function to calculate a set of output values of the set of output characteristics to generate a quantity of explorer design solutions for the target part within the compute duration defined by the user. Thus, by automatically generating a design specification for the target part, the computer system enables the user to quickly understand the feasibility of design requirements of the target part in order to explore many possible design solutions for the target part that fulfill the user's design, accuracy, and compute duration requirements.

### 12.1 Compute Duration

Generally, the computer system can: interface with the design portal to prompt the user to define a compute duration for the design problem; and define a mesh type and a mesh density (i.e., a quantity of elements per unit area in the mesh) of each function proportional to the compute duration defined by the user.

In one implementation, the computer system presents a menu within the design portal defining a set of predefined compute durations (e.g., time windows) for the design problem. The user then selects a single compute duration from this menu. For example, the computer system can: present a menu within the design portal defining a set of predefined compute durations, such as 15 minutes, 30 minutes, one hour, and two hours, for the design problem. The user may then: review the predefined compute durations for the design problem; and select a predefined compute duration, such as 15 minutes.

In one variation, the computer system: generates a slider representing a sensitivity or tolerance range of acceptable accuracy for design solutions generated according to a design specification for the target part, within the design portal; labels the selectable slider with compute durations associated with each tolerance range; interfaces with the design portal to receive selection of a particular tolerance range from the user; and identifies the compute duration associated with the particular tolerance range.

### 12.1.1 Compute Function

In one implementation, the computer system generates a compute function (e.g., a linear regression) representing a relationship between mesh density (i.e., a quantity of elements per unit area) and accuracy of explorer design solutions. For example, the computer system can: feed the proposed virtual model of the part and a test set of (e.g., 10) input values of input parameters into a function, defined in the design specification; pseudo-randomly select a set of mesh densities for the function; execute the function to calculate a corresponding test set of (e.g., 10) output values of the set of output characteristics to generate a quantity of explorer design solutions for the target part according to the set of mesh densities; and calculate a compute function representing a relationship between mesh density and accuracy of the quantity of explorer design solutions for the target part. The computer system can then receive a tolerance range of acceptable accuracy, such as an accuracy range of +/−10%, for design solutions for the target part defined by the user; define a target mesh density corresponding to the tolerance range of acceptable accuracy based on the compute function; and repeat the methods and techniques described above to generate a target quantity of design solutions that meet the tolerance range defined by the user.

### 12.1.2 Mesh Type+Mesh Density

In another implementation, the computer system characterizes a complexity score of the geometry of the target part within the virtual model and defines a mesh type and a mesh density for the target part according to the complexity score and the compute duration selected by the user. In one example, the computer system can define the mesh type proportional to the complexity score and increase the mesh density proportional to a compute duration (e.g., one hour, two hours). In another example, the computer system can define the mesh type proportional to the complexity score and decrease the mesh density proportional to a compute duration (e.g., 10 minutes, 15 minutes).

In one variation, the computer system: accesses the proposed virtual model of the target part; extracts a set of features representing geometry from a region, in a set of regions, of the virtual model of the target part; and calculates a complexity score of this region, in the set of regions, of the virtual model based on the set of features. The computer system then repeats these methods and techniques for each other region in the set of regions to calculate a total complexity score of the total geometry of the target part depicted in the virtual model based on a combination of complexity scores of the set of regions. Based on the total complexity score, the computer system selects a mesh type (e.g., a hexagonal mesh type, a tetrahedral mesh type, a hybrid mesh type) and a mesh density (i.e., a quantity of elements per unit area in the mesh) for the selected function to yield a quantity of design solutions that meet the compute duration defined by the user.

For example, the computer system can: access the function database; select a fluid dynamics function (e.g., a computational fluid dynamics simulation) responsive to correspondence (e.g., a match, a correlation) between the particular design context associated with the fluid dynamics function and the target design context; retrieve a set of boundary conditions, a material type for the impeller, and a set of rules, defined by an engineer (e.g., an expert) associated with the particular design context, for mapping the set of boundary conditions onto the virtual model of the target part from the function; extract a set of features representing geometry of the target part from the virtual model; calculate a total complexity score of the geometry of the target part based on the set of features; and, based on the total complexity score, select a hex mesh type and/or a mesh density for the fluid dynamics function to yield a quantity of design solutions that meet the compute duration defined by the user.

Therefore, the computer system can control or limit allocation of computational resources to explore many possible design solutions for the part by defining a mesh type and a mesh density of each function, associated with a selected output characteristic for the part, proportional to a compute duration (e.g., five minutes, 30 minutes, one hour) defined by the user. Additionally, the computer system can derive relationships between compute duration, accuracy, mesh density, and a quantity of design solutions and predict a target quantity of design solutions that meet the user's compute duration, accuracy, and design requirements for the target part.

### 12. Execute Virtual Model

In one variation, Blocks of the method S100 recite: selecting a first set of input values for the first set of input parameters based on ranges of input values defined for each input parameter in the set of input parameters; and, based on the first set of input values and the first subset of functions selected for the engineering design problem, executing the virtual model to generate a first set of output values for the set of output characteristics in Block S190.

In one implementation, the computer system then executes the virtual model to generate a set of output values for the set of output characteristics. In particular, the computer system can: select a first set of input values for the set of input parameters based on ranges of input values defined for each input parameter in the set of input parameters; execute the virtual model based on the first set of input values and the set of functions selected for the engineering design problem; and output a set of output values for the set of output characteristics.

Then in response to a first output value, in the set of output values, corresponding to a first output characteristic, in the set of output characteristics, falling outside of a target range defined for the first output characteristic, the computer system can: selectively modify the set of input values; and execute the virtual model based on the updated set of input values and the set of functions to output a new set of output values for the set of output characteristics. Therefore, the computer system can repeat this process to identify a combination of input values—for the set of input parameters—that yield a set of output values falling within target ranges defined for corresponding output characteristics defined for the engineering design problem.

### 12.1 Update Selected Input Parameters

In one variation, the computer system can prompt the user to select one or more additional input parameters—predicted to drive values of the set of output characteristics to within target ranges defined for the set of output characteristics—responsive to execution of a first instance of the virtual model.

In particular, in this variation, the computer system can: execute a first instance of the virtual model based on a first set of input parameter values—within a set of ranges of input values—and the set of functions selected for the engineering design problem; and generate a set of output values for the set of output characteristics responsive to execution of the first instance of the virtual model.

Then, for each output characteristic, in the set of output characteristics, the computer system can: access a value, in the set of output vales, corresponding to the output characteristic; access a target range defined for the output characteristic; and, in response to the value falling within the target range, verify successful execution of the virtual model for this output characteristic. Alternatively, in response to the value falling outside the target range, the computer system can flag the output characteristic as a failure of the virtual model. The computer system can then: execute a second instance of the virtual model based on a second set of input parameter values—within the set of ranges of input values—and the set of functions selected for the engineering design problem; and generate a second set of output values for the set of output characteristics responsive to execution of the second instance of the virtual model. The computer system can thus update input values of the set of input parameters in order to achieve output characteristics within the target ranges defined for the set of output characteristics.

Additionally or alternatively, in response to failure of the virtual model to yield output characteristics within target ranges defined for the set of output characteristics, the computer system can prompt the user to select one or more additional input parameters—and/or functions—predicted to improve results of execution of the virtual model. For example, in response to failure to yield a particular output characteristic within a target range defined for the particular output characteristics, the computer system can generate a prompt to: approve selection of an additional function—defining an additional parameter—predicted to improve results of execution of the virtual model; and to define a corresponding model variable in the virtual model. In particular, in one example, the computer system can generate a prompt stating: “Unable to achieve a result for the output characteristic within a target range. In the virtual model, define a new model variable corresponding to inner vane height.” Therefore, the computer system can then repeat this process to iteratively identify a best combination of functions and/or input parameters required to achieve the set of output characteristics defined for the engineering design problem.

The systems and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A method comprising:
accessing a textual descriptor of an engineering design problem, the textual descriptor supplied by a user via a design portal;
extracting a first set of language signals from the textual descriptor;
selecting a first set of output characteristics defined for the engineering design problem based on the first set of language signals;
accessing a function database comprising a set of functions relating input parameters to output characteristics;
from the function database, selecting a first subset of functions, in the set of functions, relating a first set of input parameters to the first set of output characteristics;
accessing a virtual model representing a design solution for the engineering design problem, the virtual model defining a first set of model variables;
linking a first subset of input parameters, in the first set of input parameters, to a first subset of model variables, in the first set of model variables, each model variable, in the first subset of model variables, analogous to an input parameter in the first subset of input parameters;
in response to the first set of model variables omitting a model variable analogous to a first input parameter in the first set of input parameters:
generating a prompt to update the virtual model to include a first model variable analogous to the first input parameter;
transmitting the prompt to the user via the design portal; and
in response to receiving confirmation of the first model variable in the virtual model:
linking the first input parameter to the first model variable; and
inserting the first input parameter in the first subset of input parameters;
for each input parameter, in the first subset of input parameters, defining a range of input values, in a set of ranges of input values, of the input parameter;
compiling the first set of functions, the first set of output characteristics, the first set of input parameters, and the set of ranges of input values into a design specification for the engineering design problem; and
presenting the design specification to the user via the design portal.

2. The method of claim 1:
further comprising, for each input parameter in a second subset of input parameters, in the first set of input parameters and omitted from the first subset of input parameters, assigning a fixed value, in a set of fixed values, to the input parameter; and
wherein compiling the first set of functions, the first set of output characteristics, the first set of input parameters, and the set of ranges of input values into the design specification comprises compiling the first set of functions, the first set of output characteristics, the first set of input parameters, the set of ranges of input values, and the set of fixed values into the design specification.

3. The method of claim 1:
wherein accessing the first set of output characteristics comprises:
interpreting a target design context based on the first set of language signals;
predicting a first set of output characteristics for the target part based on historical design data for parts associated with the target design context;
presenting the first set of output characteristics to the user via the design portal; and
receiving selection of a first subset of output characteristics, in the first set of output characteristics, from the user via the design portal.

4. The method of claim 3:
wherein predicting the first set of output characteristics comprises:
querying a language model for output characteristics of parts related to language signals approximating the first set of language signals; and
assigning the first set of output characteristics to the engineering design problem, the first set of output characteristics output by the language model.

5. The method of claim 1:
wherein linking the first input parameter to the first model variable comprises:
extracting a second set of language signals from the first model variable defined in the virtual model;
deriving a first correlation between the second set of language signals and a description of a first input parameter in the set of input parameters; and
in response to the first correlation exceeding a threshold correlation, linking the first model variable to the first input parameter.

6. The method of claim 1:
wherein generating the prompt to update the virtual model to include the second model variable comprises:
generating a description of the second model variable;
generating a recommended identifier for the second model variable in the virtual model; and
generating the prompt to update the virtual model to include the second model variable, the prompt comprising the description of the second model variable and the recommended identifier; and
wherein linking the second input parameter to the second model variable in response to receiving confirmation of the second model variable in the virtual model comprises linking the second input parameter to the second model variable in response to identifying the second model variable in the virtual model based on the recommended identifier.

7. The method of claim 1:
wherein selecting the first subset of functions comprises selecting the first subset of functions, in the set of functions, relating the first set of input parameters to the first set of output characteristics, the first subset of functions defining a quantity of unique input parameters less than each other subset of functions, in the set of functions, configured to yield the first set of output characteristics.

8. The method of claim 1:
wherein selecting the first subset of functions comprises selecting the first subset of functions defining a first quantity of functions less than each other subset of functions, in the set of functions, configured to yield the first set of output characteristics.

9. The method of claim 1, further comprising:
in response to the first set of model variables comprising a second model variable omitted from the first subset of model variables:
generating a second prompt comprising a request to discard the second model variable from the virtual model;
transmitting the second prompt to the user via the design portal; and
in response to rejection of the request to discard the second model variable from the virtual model by the user, selecting a new function, in the set of functions, defining a second input parameter analogous to the second model variable.

10. The method of claim 1, further comprising:
in response to the first set of model variables comprising a second model variable omitted from the first subset of model variables:
generating a second prompt comprising a request to discard the second model variable from the virtual model;
transmitting the second prompt to the user via the design portal; and
in response to rejection of the request to discard the second model variable from the virtual model by the user, assigning a fixed value to the second model variable.

11. The method of claim 1:
wherein defining the range of input values of the input parameter comprises, for each input parameter, in the first set of input parameters:
querying a language model for scientific data associated with the input parameter;
retrieving a corpus of scientific data, for the input parameter, output by the language model; and
based on the corpus of scientific data, defining the range of input values of the input parameter.

12. The method of claim 1:
wherein accessing the textual descriptor of the engineering design problem comprises accessing the textual descriptor of the engineering design problem associated with designing an impeller for wastewater treatment; and
wherein selecting the first subset of functions relating the first set of input parameters to the first set of output characteristics comprises selecting the first subset of functions relating the first set of input parameters to the first set of output characteristics, the first set of input parameters comprising a quantity of blades, an angle of attack, and an impeller diameter.

13. The method of claim 1, further comprising, in response to receiving confirmation of the design specification from the user via the design portal:
selecting a first set of input values for the first set of input parameters based on ranges of input values defined for each input parameter in the set of input parameters; and
based on the first set of input values and the first subset of functions selected for the engineering design problem, executing the virtual model to generate a first set of output values for the set of output characteristics.

14. The method of claim 13, further comprising:
for a first output characteristic in the first set of output characteristics, accessing a first target range of values defined for the first output characteristic;
accessing a first output value, in the first set of output values, generated for the first output characteristic; and
in response to the first output value falling outside the first target range of values defined for the first output characteristic:
selecting a second set of input values for the first set of input parameters based on ranges of input values defined for each input parameter, in the set of input parameters, and based on a first difference between the first output value and the first target range of values; and
based on the second set of input values and the first subset of functions selected for the engineering design problem, executing the virtual model to generate a second set of output values for the set of output characteristics.

15. The method of claim 13, further comprising:
for a first output characteristic in the first set of output characteristics, accessing a first target range of values defined for the first output characteristic;
accessing a first output value, in the first set of output values, generated for the first output characteristic; and
in response to the first output value falling outside the first target range of values defined for the first output characteristic:
selecting a new input parameter, omitted from the first set of input parameters, predicted to drive the first output value of the first output characteristic toward the first target range of values;
generating a prompt to include the new input parameter; and
transmitting the prompt to the user.

16. A method comprising:
accessing a textual descriptor of an engineering design problem, the textual descriptor supplied by a user via a design portal;
extracting a first set of language signals from the textual descriptor;
accessing a first set of output characteristics defined for the engineering design problem;
accessing a virtual model representing a design solution for the engineering design problem, the virtual model defining a first set of model variables;
accessing a function database comprising a set of functions relating input parameters to output characteristics;
from the function database, identifying a first subset of functions, in the set of functions, relating a first set of input parameters to the first set of output characteristics, the first set of input parameters analogous to the first set of model variables; and
in response to a first function, in the first subset of functions, defining a first input parameter and in response to the first set of model variables omitting an model variable analogous to the first input parameter:
generating a prompt to update the virtual model to include a first model variable analogous to the first input parameter; and
transmitting the prompt to the user via the design portal.

17. The method of claim 16, further comprising:
for each input parameter, in the first set of input parameters, defining a range of input values, in a set of ranges of input values, of the input parameter;
compiling the first subset of functions, the first set of output characteristics, the first set of input parameters, and the set of ranges of input values into a design specification for the engineering design problem; and
presenting the design specification to the user via the design portal.

18. The method of claim 16, further comprising:
for each input parameter, in the first set of input parameters, defining a range of input values, in a set of ranges of input values, of the input parameter; and
based on the virtual model and the set of ranges of input values, executing each function, in the first subset of functions, to derive a set of output values of the set of output characteristics.

19. The method of claim 16, wherein identifying the first subset of functions relating the first set of input parameters, analogous to the first set of model variables, to the first set of output characteristics, comprises;
identifying a first subset of model variables, in the set of model variables, predicted to exhibit correlations exceeding a threshold correlation to the first set of output characteristics;
identifying a second subset of model variables, in the set of model variables, predicted to exhibit correlations less than the threshold correlation to the first set of output characteristics;
assigning a first set of fixed values to model variables in the second subset of model variables; and
identifying the first subset of functions relating the first set of input parameters, analogous to the first subset of model variables, to the first set of output characteristics.

20. A method comprising:
via a design portal, receiving a digital object depicting a part and a set of natural language terms;
interpreting a target design context from the set of natural language terms;
extracting a set of features representing a geometry of the target part from the digital object;
deriving a virtual model of the target part based on the set of features and the target design context;
predicting a first set of output characteristics for the target part based on historical design data of the target part and associated with the target design context;
accessing a function database;
selecting a set of functions associated with a second set of output characteristics corresponding to the first set of output characteristics within the function database;
for each function in the set of functions:
extracting an input parameter, in a set of input parameters, from the function;
accessing a corpus of scientific data; and
defining a range of input values of the input parameter, in the set of input parameters, based on the corpus of scientific data;
presenting the virtual model and the first set of output characteristics for the target part to a user via the design portal; and
in response to receiving confirmation of the virtual model and the set of output characteristics from the user via the design portal:
compiling ranges of input values and the set of functions into a design specification for the target part; and
rendering the design specification for the target part within the design portal.
